(19) United States
(12) Patent Application Publication
(10) Pub. No.: US 2017/0067618 A1
(43) Pub. Date: Mar. 9, 2017

(54) LIGHTING APPARATUS

(71) Applicant: Kyocera Connector Products Corporation, Yokohama-shi, Kanagawa (JP)

(72) Inventors: Toru Wagatsuma, Yokohama-shi, Kanagawa (JP); Hiromitsu Kurimoto, Yokohama-shi, Kanagawa (JP); Atsushi Sato, Yokohama-shi, Kanagawa (JP)

(21) Appl. No.: 15/122,785

(22) PCT Filed: Dec. 26, 2014
(86) PCT No.: PCT/JP2014/084520

§ 371 Date: Aug. 31, 2016

(30) Foreign Application Priority Data
Mar. 6, 2014 (JP) 2014-043706

(51) Int. Cl. F21V 13/04; F21V 3/04; H01L 25/075; F21V 19/00; H01L 33/58; F21V 5/04; F21V 7/22

(52) U.S. Cl. CPC F21V 13/04; F21V 5/04; F21V 3/049; F21V 7/22; F21V 19/0015; H01L 33/58; H01L 25/0753; F21Y 2105/10

(57) ABSTRACT

A lighting apparatus that, despite using an optical element whose front and back surfaces are both flat, can efficiently diffuse illumination light of a semiconductor light-emitting element to prevent luminance unevenness and the like is provided. The lighting apparatus includes: a base member (30, 45, 54); a semiconductor light-emitting element (62) fixed to the base member; and an optical element (70) whose surface (70b) facing the semiconductor light-emitting element and surface (70a) on an opposite side to the semiconductor light-emitting element are flat surfaces parallel to each other, wherein the optical element has a plurality of at least either recesses (71, 72) or through holes, in at least one of the facing surface and the opposite surface.

### CROSS REFERENCE TO RELATED APPLICATION

Applicant hereby claims foreign priority benefits under U.S.C. §119 from International Patent Application Serial No. PCT/JP2014/084520 filed on Dec. 26, 2014 and Japanese Patent Application No. 2014-043706 filed on Mar. 6, 2014, the contents of all of which are incorporated by reference herein.

### TECHNICAL FIELD

The disclosure relates to a lighting apparatus using a semiconductor light-emitting element (light-emitting diode (LED)).

### BACKGROUND

A conventional lighting apparatus using a semiconductor light-emitting element (LED) is disclosed, for example, in JP 2006-114863 A.

This lighting apparatus includes a base member, an LED (semiconductor light-emitting element) fixed to the base member, and a light distribution lens (optical element) fixed to the base member.

Light emitted from the LED has high straightness. Accordingly, the illumination light of the LED that has passed through the light distribution lens travels in one specific direction (and its surrounding part) without diffusing much, unless the shape of the light distribution lens is improved. In the case where the light distribution lens has such light distribution property, the usefulness of the lighting apparatus is low.

In view of this, JP 2006-114863 A improves the shape of the light distribution lens to diffuse the illumination light. The light distribution lens in JP 2006-114863 A is a rotationally symmetric body whose central axis is orthogonal to the light emission surface of the LED, and has, in its surface facing the LED (and the base member), a rotationally symmetric recess centering on the axis.

The light distribution lens is fixed to the base member so as to cover the LED. The LED is situated in the space between the recess and the base member.

When power generated from a power source is supplied to the LED, the LED emits light.

The illumination light emitted from the LED enters the light distribution lens from the surface of the recess (the inner peripheral surface of the light distribution lens). The illumination light then passes through the light distribution lens, and comes out of the light distribution lens from the outer peripheral surface of the light distribution lens. The illumination light is thus diffused in various directions by the light distribution lens.

### SUMMARY

In JP 2006-114863 A, the entire surface of the light distribution lens opposite to the LED is a curved surface.

However, the light distribution lens having such a shape is hard to be formed or worked on, and also a large amount of material is needed to produce one light distribution lens. Thus, the cost of manufacturing the light distribution lens is high.

Besides, the increased thickness of the light distribution lens causes an increase in thickness of the entire lighting apparatus.

This problem may be solved by forming the light distribution lens with a planar member whose front and back surfaces (the surface facing the LED and the surface opposite to the facing surface) are both flat.

The planar light distribution lens, however, has a poor function of diffusing the illumination light. The lighting apparatus using the planar light distribution lens therefore tends to be bright only in the direction of the axis and its surrounding part, and dark in the other parts. In other words, the illumination light emitted from the planar light distribution lens tends to be uneven in luminance. The usefulness of such a lighting apparatus is low.

It could therefore be helpful to provide a lighting apparatus that, despite using an optical element whose front and back surfaces are both flat, can efficiently diffuse illumination light of a semiconductor light-emitting element to prevent luminance unevenness and the like.

A lighting apparatus according to the disclosure includes: a base member; a semiconductor light-emitting element fixed to the base member; and an optical element whose surface facing the semiconductor light-emitting element and surface on an opposite side to the semiconductor light-emitting element are flat surfaces parallel to each other, wherein the optical element has a plurality of at least either recesses or through holes, in at least one of the facing surface and the opposite surface.

At least either the recesses or the through holes may be formed in the facing surface and the opposite surface.

The recesses formed in the facing surface and the recesses formed in the opposite surface may be concentric with each other.

At least either the recesses or the through holes may be arranged concentrically.

At least either the recesses or the through holes may be arranged radially.

At least either the recesses or the through holes may be arranged in a grid.

At least one of the recesses may be shaped like a cone.

At least one of the recesses may be shaped like a hemisphere.

At least one of the recesses may have a bottom surface shaped like a part of a spherical surface, and a part except the bottom surface shaped like a cylinder.

At least one of the recesses may have a bottom surface shaped like a cone projecting toward an open end of the recess, and a part except the bottom surface shaped like a cylinder.

At least one of the recesses and/or at least one of the through holes may be shaped like a cylinder.

At least one of the recesses and/or at least one of the through holes may be shaped like a truncated cone.

In the lighting apparatus according to the disclosure, the surface of the optical element facing the semiconductor light-emitting element and the surface of the optical element opposite to the semiconductor light-emitting element are flat surfaces parallel to each other. In other words, the optical element according to the disclosure has a planar shape.

Such an optical element has good formability and workability, and also the amount of material needed to produce one optical element can be reduced. The optical element can therefore be manufactured at low cost.

Moreover, the thickness of the optical element is reduced, which prevents an increase in thickness of the entire lighting apparatus.

Furthermore, the optical element has a plurality of at least either recesses or through holes, in at least one of the facing surface and opposite surface.

Illumination light incident on the inner surface of such a recess or through hole is reflected off the inner surface in a direction different from the incident direction.

This enables the efficient diffusion of the illumination light despite the planar shape of the (entire) optical element.

### BRIEF DESCRIPTION OF THE DRAWINGS

In the accompanying drawings:

FIG. 1 is a top perspective view of part of a conductor plate according to one of the disclosed embodiments;

FIG. 2 is a top perspective view of a primary integrated component obtained by integrally forming a primary resin molded portion with the conductor plate;

FIG. 3 is a bottom perspective view of the primary integrated component;

FIG. 4 is a plan view of the primary integrated component;

FIG. 5 is a plan view of the primary integrated component that has undergone primary cutting;

FIG. 6 is a top perspective view of the primary integrated component and heatsink separate from each other;

FIG. 7 is a bottom perspective view of the primary integrated component and heatsink separate from each other;

FIG. 8 is a top perspective view of a combined body of the primary integrated component and heatsink;

FIG. 9 is a bottom perspective view of the combined body of the primary integrated component and heatsink;

FIG. 10 is a top perspective view of a secondary integrated component obtained by integrally forming a secondary resin molded portion with the combined body of the primary integrated component and heatsink;

FIG. 11 is a bottom perspective view of the secondary integrated component;

FIG. 12 is a plan view of the secondary integrated component with a reflective film formed on its mounting surface;

FIG. 13 is a top perspective view of an LED holder completed as a result of secondary cutting and LEDs;

FIG. 14 is a sectional view along arrow XIV-XIV in FIG. 13;

FIG. 15 is a plan view of an LED module;

FIG. 16 is a top perspective view of the LED module and light distribution lens separate from each other;

FIG. 17 is a bottom perspective view of the LED module and light distribution lens separate from each other;

FIG. 18 is a plan view of the light distribution lens;

FIG. 19 is a bottom view of the light distribution lens with fixing legs being omitted;

FIG. 20 is a sectional view along arrow XX-XX in FIG. 18;

FIG. 21 is an enlarged sectional view of part XXI in FIG. 20;

FIG. 22 is a top perspective view of one end of a connector-equipped cable and its neighboring part;

FIG. 23 is a bottom perspective view of one end of the connector-equipped cable and its neighboring part;

FIG. 24 is a plan view of a lighting apparatus with a light distribution lens being omitted, in which the lower surface of the heatsink of one LED module is fixed to the upper surface of a heat dissipation member and also the connector of the connector-equipped cable is connected;

FIG. 25 is a schematic plan view of the lighting apparatus in FIG. 24 with a translucent cover and a chassis being omitted;

FIG. 26 is an enlarged sectional view of a first modification as in FIG. 21;

FIG. 27 is an enlarged sectional view of a second modification as in FIG. 21;

FIG. 28 is an enlarged sectional view of a third modification as in FIG. 21;

FIG. 29 is an enlarged sectional view of a fourth modification as in FIG. 21; and

FIG. 30 is an enlarged sectional view of a fifth modification as in FIG. 21.

### DETAILED DESCRIPTION

The following describes one of the disclosed embodiments with reference to drawings. Note that the directions such as front, back, right, left, up, and down in the following description are based on the arrow directions in the drawings.

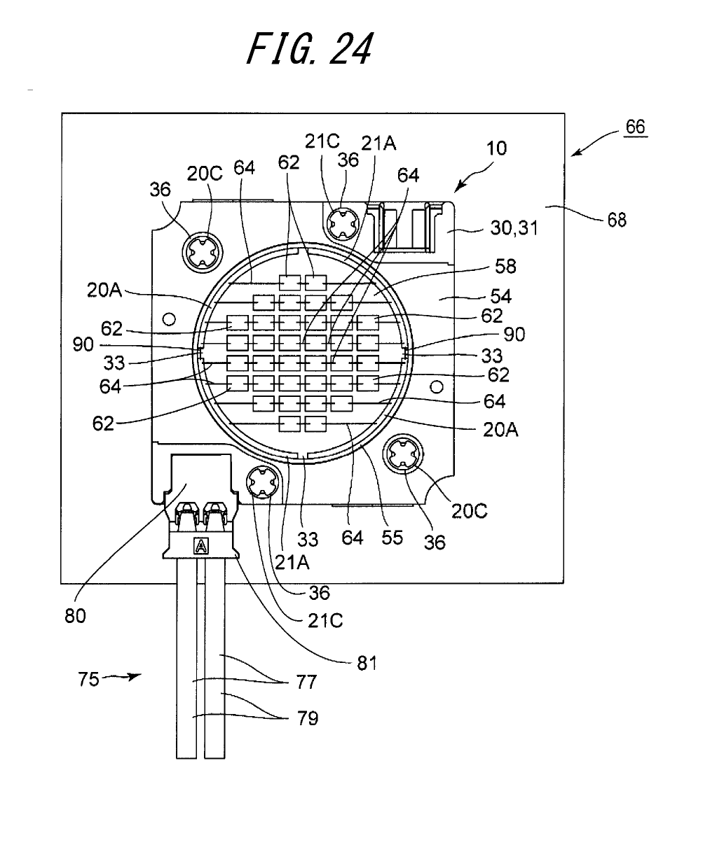

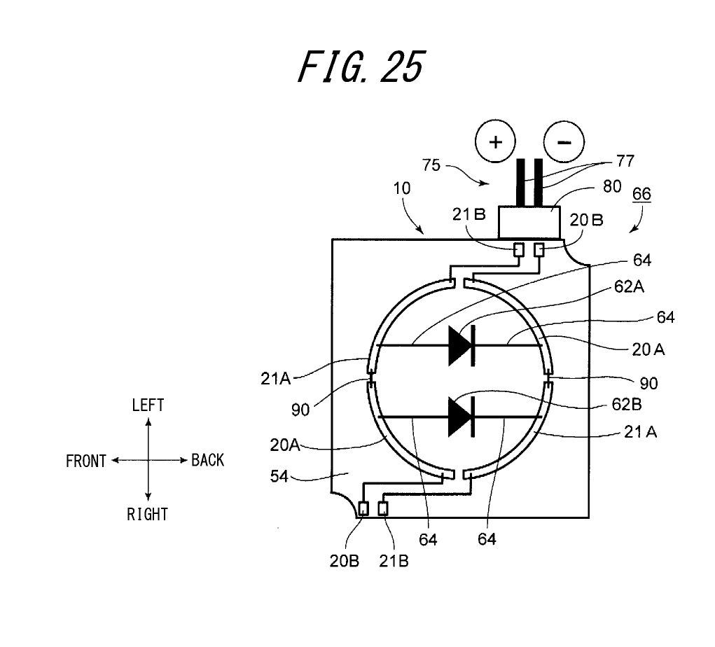

In this embodiment, an LED module 10 is used as a light source for a lighting apparatus 66 (see FIGS. 24 and 25).

The LED module 10 (semiconductor light-emitting element module) is obtained by integrally attaching LEDs 62, wire bondings 64, and a sealant (and also the below-mentioned wire bondings 90 in some cases) to an LED holder 15 (semiconductor light-emitting element holder). The detailed structure and manufacturing procedure of the LED holder 15 are described first.

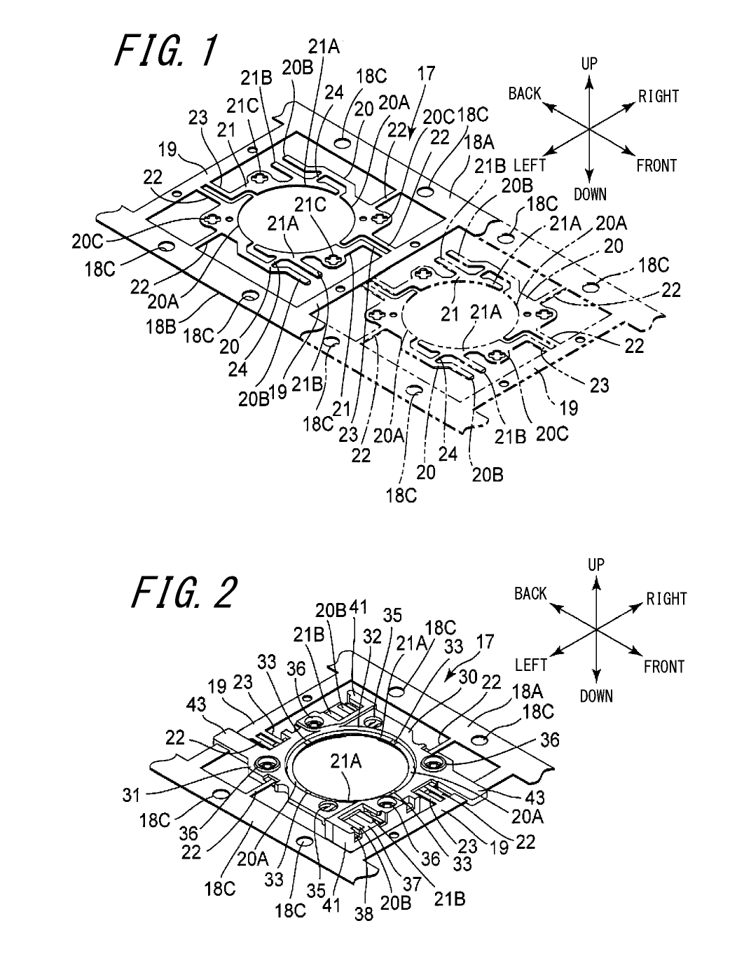

FIG. 1 illustrates a conductor plate 17 which serves as a substrate for the LED holder 15. The conductor plate 17 is, for example, obtained by stamping molding a flat plate made of metal excellent in electrical conductivity, thermal conductivity, and rigidity, such as brass, beryllium copper, or Corson copper alloy. The entire conductor plate 17 has a long planar shape (only part of the conductor plate 17 is illustrated in FIG. 1) extending in the front-back direction. Carrier sections 18A and 18B each extending in the front-back direction are formed on the right and left sides of the conductor plate 17, and carrier-connector sections 19 spaced at regular intervals in the front-back direction connect a plurality of parts of the carrier sections 18A and 18B. Conveyor holes 18C are drilled at regular intervals in each of the carrier sections 18A and 18B. Two first conductive members 20 and two second conductive members 21 are formed in each part surrounded by the carrier sections 18A and 18B and two adjacent carrier-connector sections 19. The two first conductive members 20 are each integral with a corresponding one of the carrier sections 18A and 18B and a corresponding one of the carrier-connector sections 19 via two first cutoff bridges 22, and the two second conductive members 21 are each integral with a corresponding one of the carrier-connector sections 19 via one second cutoff bridge 23. The adjacent first conductive member 20 and second conductive member 21 are connected to each other by one third cutoff bridge 24. An arc-shaped wire connecting section 20A is formed on the inner periphery of each first conductive member 20. A cable connecting section 20B linearly extending in the direction parallel to the carrier sections 18A and 18B projects in a part of the first conductive member 20 different from the wire connecting section 20A, and also a non-circular engagement hole 20C is drilled in another part of the first conductive member 20 different from the wire connecting section 20A. An arc-shaped (the same shape as the wire connecting section 20A) wire connecting section 21A is formed on the inner periphery of each second conductive member 21. A cable connecting section 21B linearly extending in the direction parallel to the cable connecting section 20B projects in a part of the second conductive member 21 different from the wire connecting section 21A, and also a non-circular engagement hole 21C is drilled in another part of the second conductive member 21 different from the wire connecting section 21A.

The conductor plate 17 having such a structure is conveyed frontward by engaging sprockets of a conveyor (not illustrated) with the respective conveyor holes 18C of the conductor plate 17 and rotating the sprockets. When the conductor plate 17 is conveyed to a predetermined position, a primary molding die (not illustrated) composed of a pair of dies located above and below the conductor plate 17 is closed so that the conductor plate 17 is housed inside the primary molding die. When the conductor plate 17 is conveyed to the predetermined position, many support pins (not illustrated) provided on the primary molding die fit into positioning holes (not illustrated) formed in the conductor plate 17, and thus the conductor plate 17 is fixed inside the primary molding die. Injection molding (insert molding, primary molding) is then performed in the primary molding die, using a resin material (e.g. liquid crystal polymer) with high insulation property and high heat resistance. After the resin material cures, the dies of the primary molding die are separated up and down from the conductor plate 17. As a result, a plurality of integrated components (hereafter referred to as “primary integrated components”) obtained by integrally forming a plurality of primary resin molded portions 30 on the surface of the conductor plate 17 are produced (only one primary integrated component is illustrated in FIGS. 2 to 4, etc.).

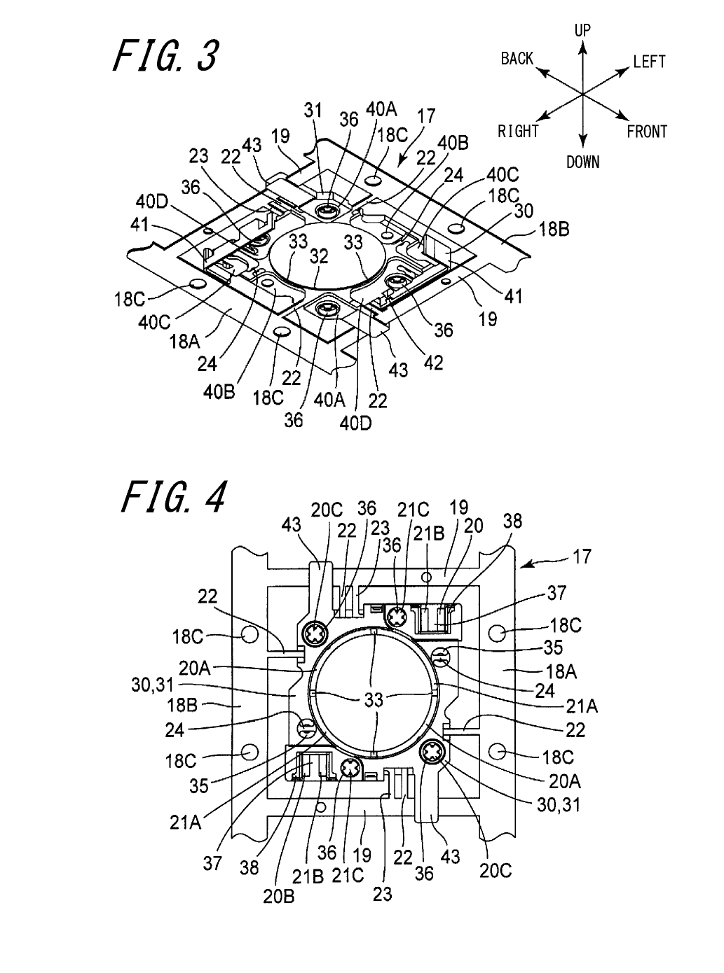

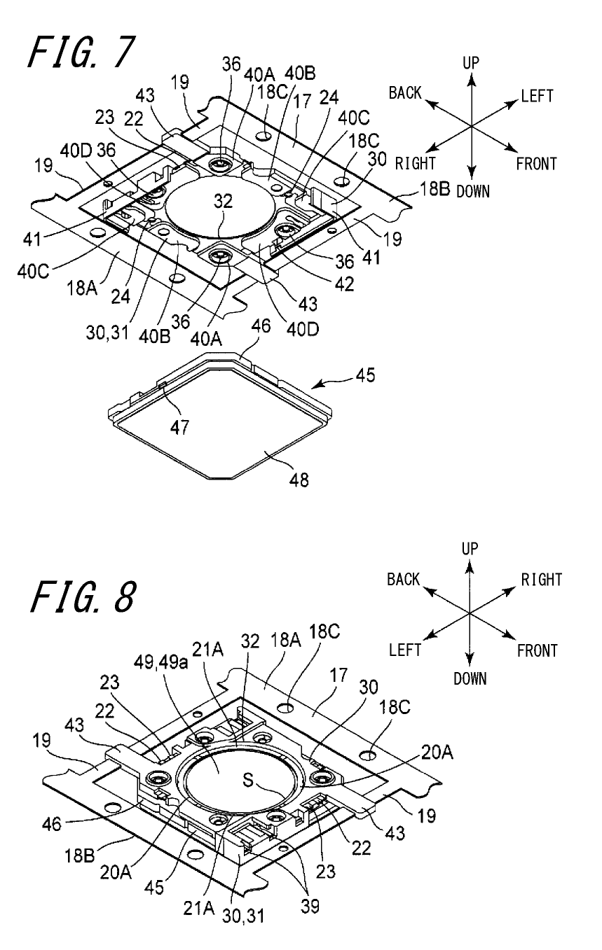

As illustrated, each primary resin molded portion 30 (base member) includes: a body portion 31 substantially square-shaped in a plan view, which is integral with the first conductive members 20, the second conductive members 21, the first cutoff bridges 22, the second cutoff bridges 23, and the third cutoff bridges 24 and has a circular through hole at its center; and two connection arms 43 extending from two parts of the body portion 31 and integral with the front and back carrier-connector sections 19. The body portion 31 includes: an annular inner wall portion 32 circular in a plan view (and tapered), which forms the outline of the through hole; and four inner projections 33 continuous with four parts of the inner periphery portion of the annular inner wall portion 32 and each filling the space between the adjacent ends of the first conductive member 20 and second conductive member 21. Moreover, two bridge exposure holes 35 exposing the respective third cutoff bridges 24 are formed on the upper surface of the body portion 31, and engagement hole exposure holes 36 exposing the engagement holes 20C and the engagement holes 21C are formed in four parts of the upper and lower surfaces of the body portion 31. In addition, a connector connection projection 37 integral with the cable connecting section 20B and the cable connecting section 21B while exposing the upper surfaces of the tips of the cable connecting section 20B and cable connecting section 21B, a connector connection groove 38 formed around the connector connection projection 37, and two engagement recesses 39 formed in both side surfaces (right and left surfaces) of the connector connection groove 38 are formed in each of two parts of the body portion 31. Eight lower-side projections 40A, 40B, 40C, and 40D projecting more downward than the conductor plate 17 are formed in the lower surface of the primary resin molded portion 30. The primary resin molded portion 30 also has two outer peripheral walls 41 substantially L-shaped in a cross section and projecting more downward than the lower-side projections 40A, 40B, 40C, and 40D. One engagement claw 42 is formed on the inner surface of each outer peripheral wall 41 (only one engagement claw 42 is illustrated in FIGS. 3 and 7).

Each primary integrated component (the conductor plate 17 and the primary resin molded portion 30) is then conveyed frontward to a predetermined position by the conveyor, and each of the first cutoff bridges 22, second cutoff bridges 23, and third cutoff bridges 24 of the conductor plate 17 is cut by a primary cutter (not illustrated) placed at the predetermined position (primary cutting). In detail, each of the first cutoff bridges 22 and second cutoff bridges 23 is cut in the direction parallel to the outer peripheral surface of the body portion 31 of each primary resin molded portion 30, and also each of the third cutoff bridges 24 is cut at its center using the bridge exposure hole 35 (see FIG. 5).

Each primary integrated component is then conveyed frontward to a predetermined position by the conveyor.

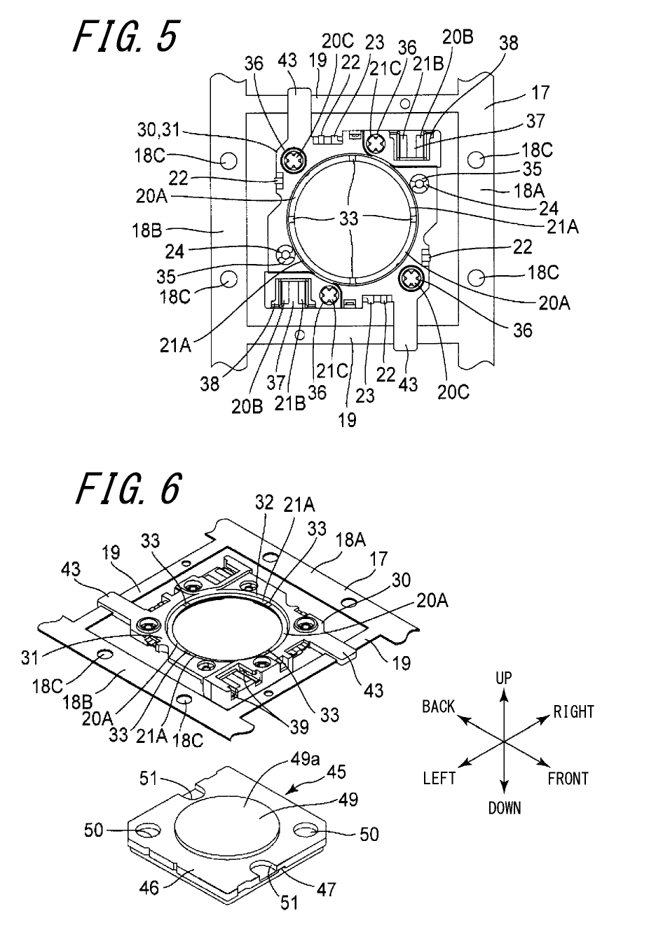

A plurality of heatsinks 45 (base members) (heat transfer members) (as many as the primary integrated components) are arranged at the predetermined position so that, when the primary integrated components are conveyed to the predetermined position, the heatsinks 45 are each located directly below a different one of the primary integrated components (FIGS. 6 and 7).

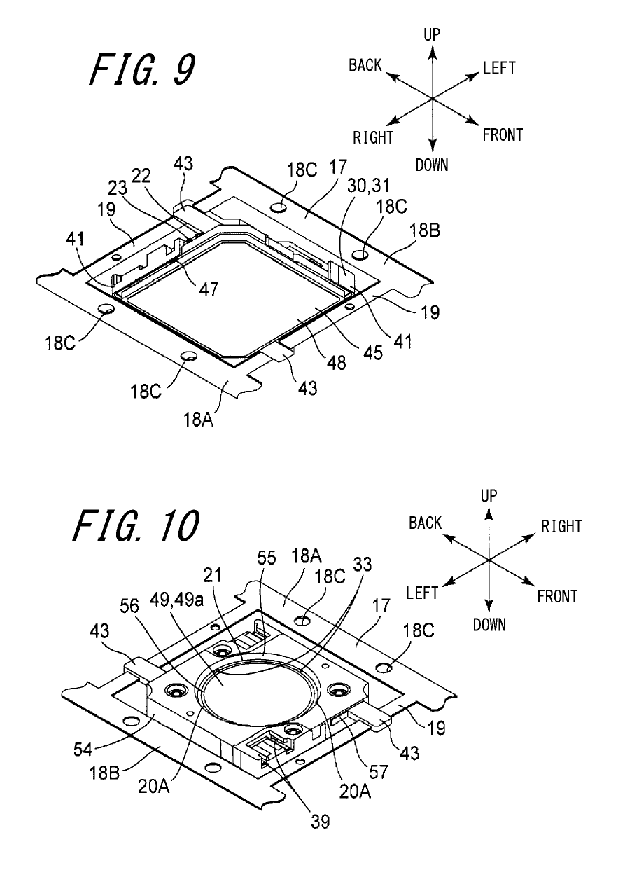

The heatsink 45 is an integrally molded component made of metal such as aluminum, and has higher thermal conductivity than the primary resin molded portion 30 (and the below-mentioned secondary resin molded portion 54). The outline of the heatsink 45 is substantially the same as that of the body portion 31. The upper half of the heatsink 45 is a housed portion 46 slightly larger in planar shape than the lower half of the heatsink 45, and locking recesses 47 are formed in two parts of the lower surface of the outer peripheral portion of the housed portion 46 (only one locking recess 47 is illustrated in FIGS. 7 and 9). The lower surface of the heatsink 45 is a contact surface 48 which is a flat surface. An LED support portion 49 shaped like a low cylinder projects from the center of the upper surface of the heatsink 45. The upper surface of the LED support portion 49 is a mounting surface 49a which is a horizontal flat surface. Moreover, two circular recesses 50 and two non-circular recesses 51 are formed in the upper surface of the heatsink 45.

When each primary integrated component (the conductor plate 17 and the primary resin molded portion 30) is located directly above the corresponding heatsink 45, the conveyor raises the heatsink 45 toward the primary integrated component (see FIGS. 8 and 9). As a result, the housed portion 46 of the heatsink 45 is housed in the space defined by the two outer peripheral walls 41 of the primary integrated component, where parts (two parts) of the outer peripheral surface of the housed portion 46 face the inner peripheral surfaces of the two outer peripheral walls 41 with a minute clearance in between and also the upper surface of the housed portion 46 is in surface contact with the lower surfaces of the lower-side projections 40A, 40B, 40C, and 40D. Here, the four ridges (the downward ridges located around the respective four engagement hole exposure holes 36) formed on the lower surface of the primary integrated component (the body portion 31) respectively fit into the two circular recesses 50 and the two non-circular recesses 51. In addition, the two engagement claws 42 engage with the two locking recesses 47 from below. The heatsink 45 is thus temporarily fixed to the body portion 31 (the body portion 31 and the heatsink 45 are integral with each other). Further, the LED support portion 49 freely fits into the circular hole at the center of the body portion 31. The outer peripheral surface of the LED support portion 49 is inwardly separate from the inner peripheral surfaces of the wire connecting sections 20A and wire connecting sections 21A and the inner projections 33, with an annular space S being formed in between (see FIG. 8).

Each integrated component composed of the primary integrated component (the conductor plate 17 and the primary resin molded portion 30) and the heatsink 45 is further conveyed frontward to a predetermined position by the conveyor.

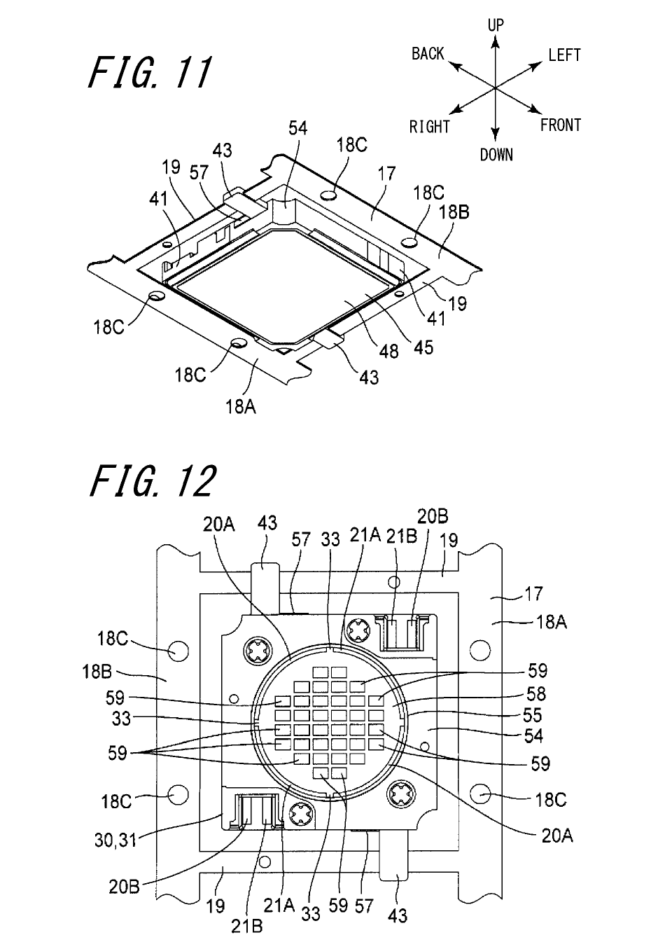

At the predetermined position, a secondary molding die (not illustrated) composed of a pair of dies located above and below the integrated component is closed so that the integrated component is housed inside the secondary molding die. Here, many support pins (not illustrated) provided on the secondary molding die fit into the aforementioned positioning holes, and thus the integrated component is fixed inside the secondary molding die. Injection molding (insert molding, secondary molding) is then performed in the secondary molding die, using a resin material (e.g. liquid crystal polymer) with high insulation property and high heat resistance. After the resin material cures, the dies of the secondary molding die are separated up and down from the integrated component. As a result, each integrated component (secondary integrated component) obtained by forming a secondary resin molded portion 54 (base member) on the surface of the integrated component composed of the primary integrated component (the conductor plate 17 and the primary resin molded portion 30) and the heatsink 45 is produced (see FIGS. 10 and 11). As illustrated, the secondary resin molded portion 54 is formed over the primary resin molded portion 30 and the heatsink 45 (covers the engagement claws 42 and the locking recesses 47). Therefore, once the secondary resin molded portion 54 has cured, the primary resin molded portion 30 and the heatsink 45 are completely fixed to each other. The secondary resin molded portion 54 has an annular wall 55 that is formed by a tapered surface circular in a plan view covering the surface of the annular inner wall portion 32 and is continuous with the upper surface of each inner projection 33. Moreover, an annular portion 56 constituting part of the secondary resin molded portion 54 fills the annular space S formed between the outer peripheral surface of the LED support portion 49 and the inner peripheral surfaces of the wire connecting sections 20A and wire connecting sections 21A and the inner projections 33 (see FIG. 10), with the upper surface of the annular portion 56 lying in the same plane as the mounting surface 49a of the LED support portion 49 and the upper surface of each inner projection 33 (i.e. being continuous with the mounting surface 49a of the LED support portion 49 and the upper surface of each inner projection 33). The secondary resin molded portion 54 also fills the gap formed between the lower surface of the primary resin molded portion 30 and the upper surface of the housed portion 46 (the gap formed between the eight lower-side projections 40A, 40B, 40C, and 40D of the primary resin molded portion 30). Covering projections 57 formed (projected) in two parts of the outer peripheral surface of the secondary resin molded portion 54 cover the ends of the first cutoff bridges 22 and second cutoff bridges 23 which were exposed before the secondary molding.

Each secondary integrated component (the conductor plate 17, the primary resin molded portion 30, the heatsink 45, and the secondary resin molded portion 54) is then conveyed frontward to a predetermined position by the conveyor.

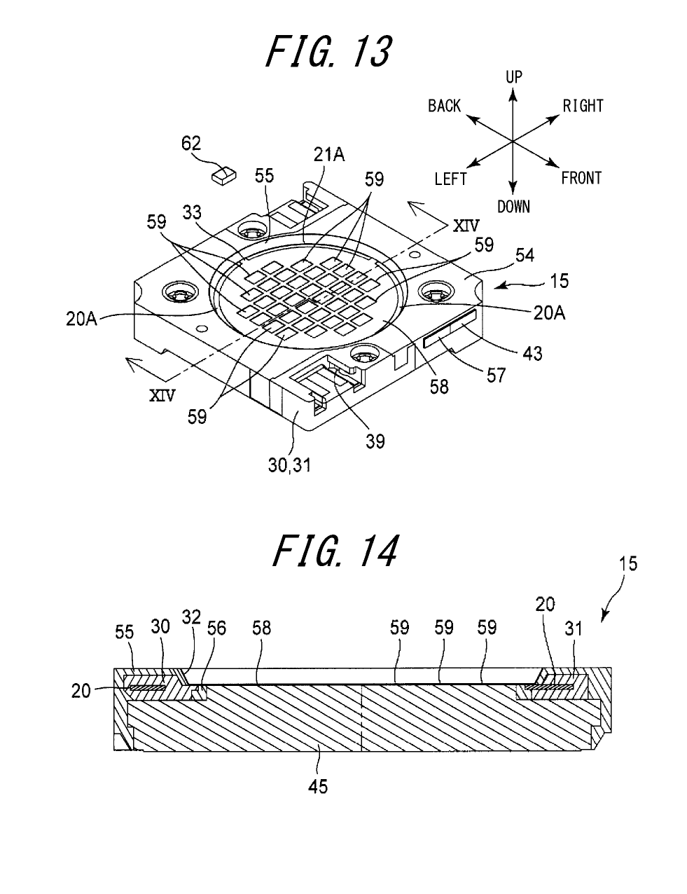

A pad printer (not illustrated) is placed at the predetermined position. When each secondary integrated component is conveyed to the predetermined position, the secondary integrated component is located in the pad printer. The pad printer then prints a reflective film 58 as a thin film of 30 μm in thickness, continuously (integrally) on the upper surfaces of the four inner projections 33, the mounting surface 49a of the LED support portion 49, the surface of the annular wall 55, and the upper surface of the annular portion 56 (see FIGS. 12 and 13). The reflective film 58 is obtained by mixing titanium oxide (TiO2) or the like as a colorant with a polyurethane resin as a main ingredient, and has insulation property as a whole. The reflective film 58 is white as it contains the colorant, and differs in color (hue) from the heatsink 45 made of aluminum. The reflective film 58 accordingly has higher visible light reflectivity than the primary resin molded portion 30, the heatsink 45, and the secondary resin molded portion 54 (specifically, the visible light reflectivity of the reflective film 58 is 90% or more, and preferably 95% or more). The reflective film 58 is formed on the LED support portion 49 while avoiding part of the mounting surface 49a. In detail, the reflective film 58 is formed on the mounting surface 49a so as to avoid many (36 in total) areas rectangular in a plan view, as illustrated in the drawings. Each area rectangular in a plan view constitutes an LED fixing portion 59 (semiconductor light-emitting element fixing portion), and there is a height difference equivalent to the thickness of the reflective film 58 between the upper surface of the reflective film 58 and the LED fixing portion 59 (the mounting surface 49a).

Each secondary integrated component is then conveyed frontward to a predetermined position by the conveyor, and each connection arm 43 is cut by a secondary cutter (not illustrated) placed at the predetermined position (secondary cutting). In detail, each connection arm 43 is linearly cut along the end surface of the corresponding covering projection 57, to separate the secondary integrated component from the carrier-connector sections 19 (and the carrier sections 18A and 18B) (see FIG. 13). This completes a plurality of LED holders 15 with no exposure of the connection parts (fracture surfaces, unwanted metal parts) with the carrier sections 18A and 18B and the carrier-connector sections 19.

The procedure of manufacturing the LED module 10 from each LED holder 15 is described next.

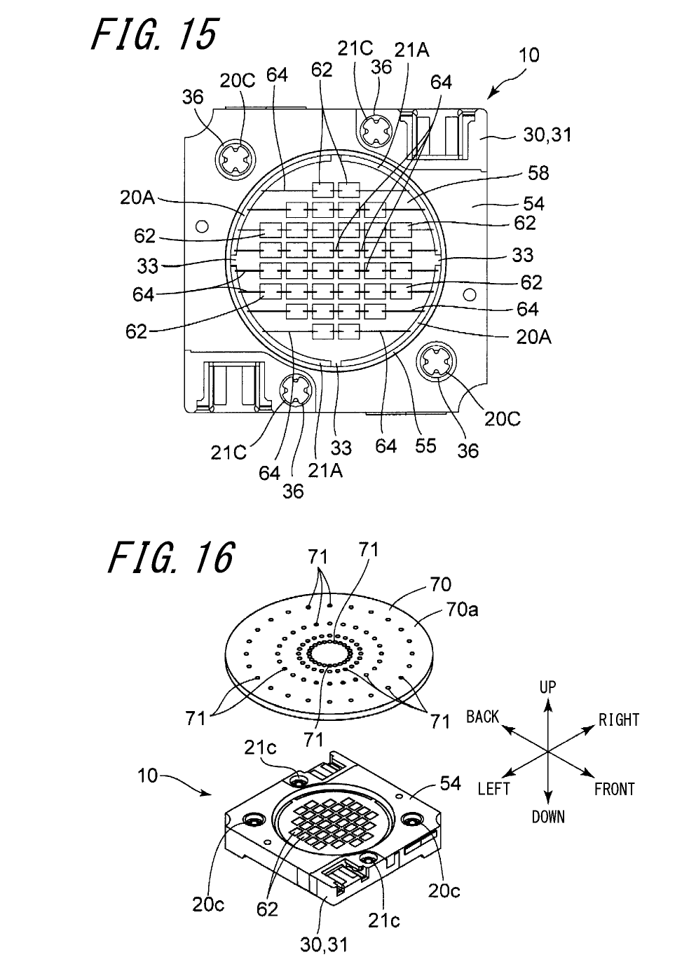

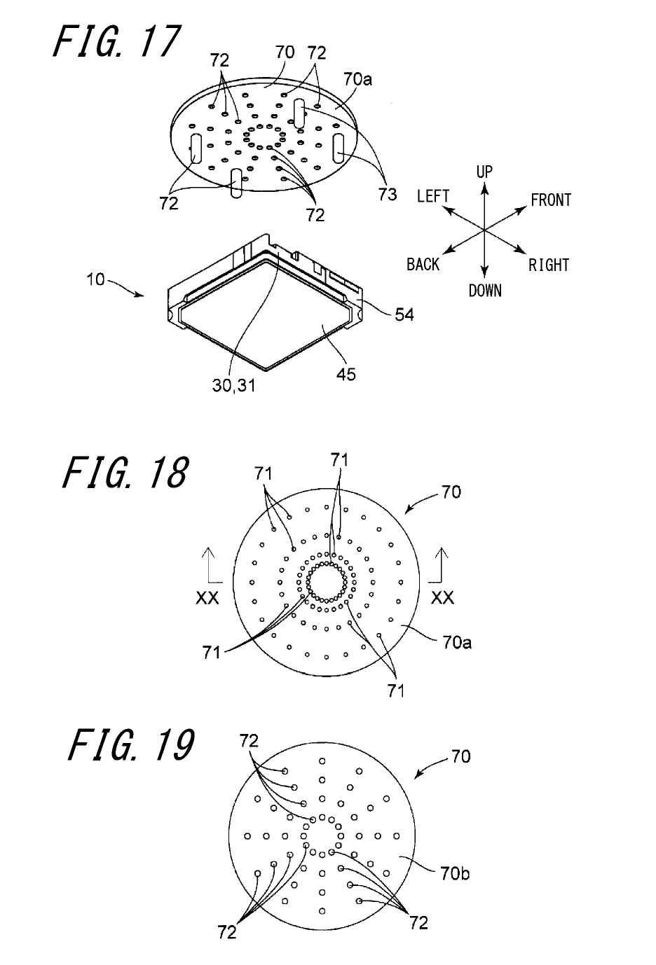

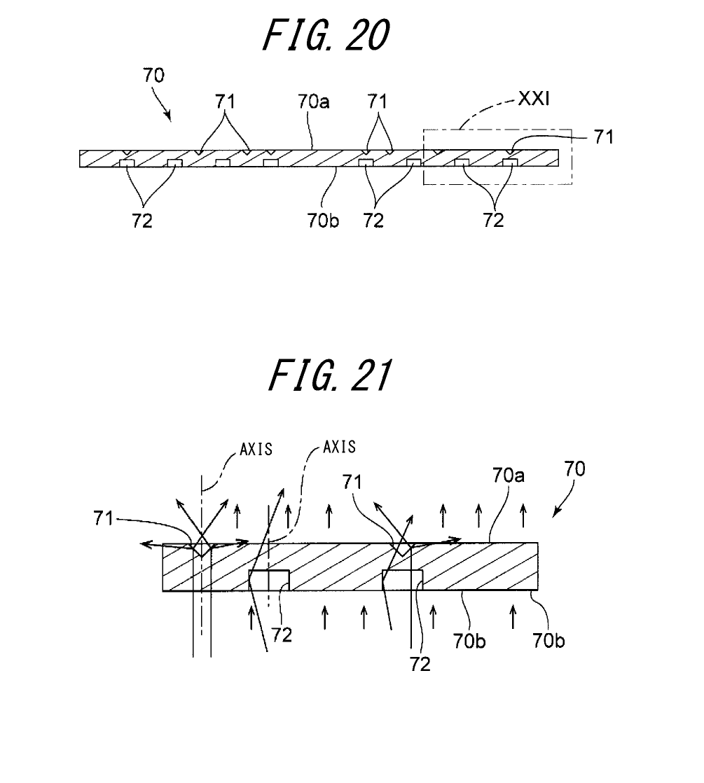

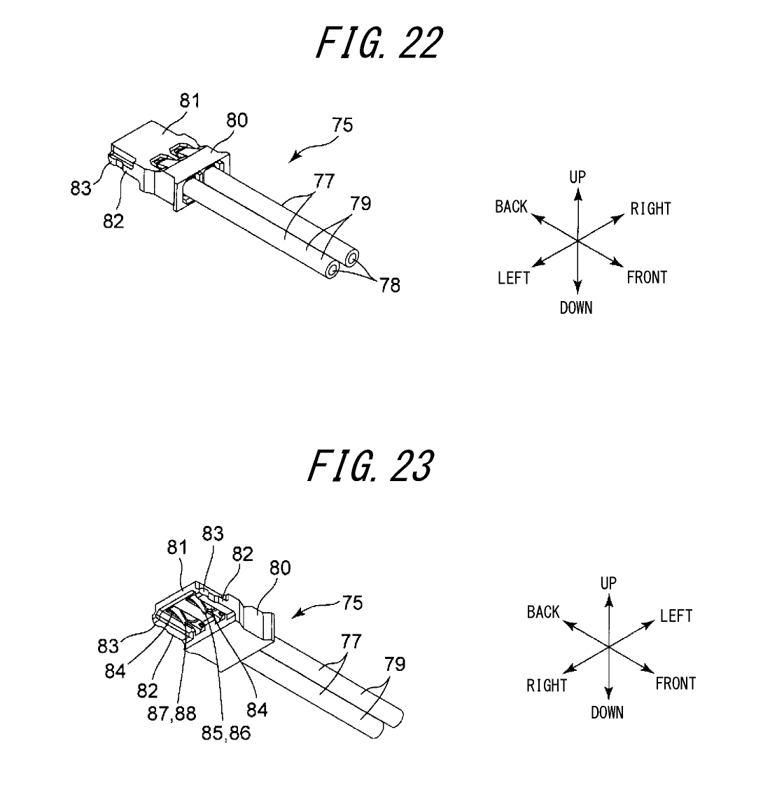

Each LED 62 (semiconductor light-emitting element) substantially shaped like a rectangular parallelepiped is fixed to the corresponding LED support portion 49 of the LED holder 15. As illustrated, each LED 62 has the substantially same planar shape as the LED fixing portion 59 (and has a slightly smaller size than the LED fixing portion 59). When fixing the LED 62 to the LED fixing portion 59, first an adhesive (not illustrated) is applied to the LED fixing portion 59 (the mounting surface 49a), and then an LED conveyor (not illustrated) places the LED 62 in the LED fixing portion 59 (see FIG. 15). Since there is a height difference equivalent to the thickness of the reflective film 58 between the upper surface of the reflective film 58 and the LED fixing portion 59 (so that the LED fixing portion 59 is a recess surrounded by the reflective film 58) as mentioned above, the LED 62 can be easily and reliably attached to (fitted into) the LED fixing portion 59. Moreover, since there is a height difference equivalent to the thickness of the reflective film 58 between the upper surface of the reflective film 58 and the LED fixing portion 59, the adhesive applied to the LED fixing portion 59 (the mounting surface 49a) is kept from flowing to the surroundings (the reflective film 58 side) of the LED fixing portion 59. The LED conveyor has a sensor for identifying hue differences, and places the LED 62 on the LED fixing portion 59 while recognizing the hue difference (boundary) between the reflective film 58 and the LED fixing portion 59 (the mounting surface 49a). This ensures that the LED 62 is placed in the LED fixing portion 59.

Following this, as illustrated in FIG. 15, the terminals exposed on the upper surfaces of the adjacent LEDs 62 fixed to the respective LED fixing portions 59 are connected by wire bondings 64 (indicated by the thick lines in FIG. 15). Moreover, the terminals of the LEDs 62 positioned facing each wire connecting section 20A and the wire connecting section 20A are connected by wire bondings 64, and the terminals of the LEDs 62 positioned facing each wire connecting section 21A and the wire connecting section 21A are connected by wire bondings 64 (and further the below-mentioned wire bondings 90 are arranged according to need).

Lastly, the upper surface of the secondary resin molded portion 54 (the circular hole inside the upper edges of the annular wall 55) is coated with a sealant (not illustrated) made of a thermosetting resin material, an ultraviolet curable resin material, or the like having translucency and insulation property. This completes the LED module 10 in which the wire connecting sections 20A, the wire connecting sections 21A, the inner projections 33, the reflective film 58, the LEDs 62, and the wire bondings 64 (90) are covered with the sealant.

The LED module 10 having the aforementioned structure can be used as a component of the lighting apparatus 66.

The lighting apparatus 66 includes a chassis 68 (heat dissipation member) which is a metal plate. The LED module 10 is fixed to the chassis 68 in a state where the contact surface 48 of the heatsink 45 is in contact with the upper surface of the chassis 68.

The lighting apparatus 66 also includes a light distribution lens 70 (optical element) and connector-equipped cable 75 removable from the LED module 10.

The light distribution lens 70 is made of a translucent material (e.g. glass or a resin such as acrylic) and shaped like a circular disc. For example, the light distribution lens 70 can be injection molded using a molding die. The front surface 70a (opposite surface) and back surface 70b (facing surface) of the light distribution lens 70 are flat surfaces parallel to each other.

Many (96 in total) recesses 71 are formed in the front surface 70a. 24 recesses 71 are arranged along each of the four circumferences that differ in diameter, concentrically and radially about the center point of the light distribution lens 70. Each recess 71 is shaped like a cone whose central axis extends in the thickness direction of the light distribution lens 70, as illustrated in FIGS. 20 and 21.

Many (48 in total) recesses 72 are formed in the back surface 70b. 12 recesses 72 are arranged along each of the four circumferences that differ in diameter, concentrically and radially about the center point of the light distribution lens 70. Each recess 72 is shaped like a cylinder whose central axis extends in the thickness direction of the light distribution lens 70, as illustrated in FIGS. 20 and 21. Four fixing legs 73 also project from the back surface 70b.

Some of the recesses 71 and some of the recesses 72 are concentric (coaxial) with each other (face each other in the up-down direction), as illustrated in FIGS. 20 and 21.

The light distribution lens 70 having such a structure is securely (but removably) attached to the LED module 10 by fitting (pressing) the four fixing legs 73 into the corresponding engagement holes 20C and engagement holes 21 C. When the light distribution lens 70 is attached to the LED module 10, the back surface 70b of the light distribution lens 70 faces the LED module 10 in the thickness direction of the light distribution lens 70 while forming a gap with the LED module 10.

The connector-equipped cable 75 is obtained by integrally forming two cables 77 with a connector 80. Each flexible cable 77 includes: an electric wire 78 obtained by bundling many metal wires; and a covering tube 79 made of an insulation material covering the surface of the electric wire 78. At both ends of each cable 77, the electric wire 78 is exposed by removing the covering tube 79. The connector 80 includes: an insulator 81 made of an insulation material; a first contact 85; and a second contact 87. Locking ridges 82 extending in the front-back direction are formed on both sides of the insulator 81 which is a hollow member, and retaining projections 83 are formed at the tips of the right and left locking ridges 82. The tip (back half) of the insulator 81 is made thinner, and two long grooves 84 communicating with the internal space of the insulator 81 are formed in the lower surface of the tip. The first contact 85 and the second contact 87 are both made of a conductive material (such as metal), and are securely inserted in the internal space of the insulator 81. The electric wire 78 at one end (back end) of each of the two cables 77 is crimped (connected) to one end (front end) of a corresponding one of the first contact 85 and the second contact 87. The other end (back end) of each of the first contact 85 and the second contact 87 is a corresponding one of an elastically deformable first contact segment 86 and second contact segment 88 projecting downward from the insulator 81 through the corresponding long grooves 84.

The connector-equipped cable 75 can be removably attached to the connector connection projection 37 and connector connection groove 38 (the cable connecting section 20B and cable connecting section 21B) of the LED module 10, as illustrated in FIG. 24. In detail, the connector 80 is inserted into the connector connection groove 38, with the right and left locking ridges 82 being fitted with the right and left sides of the connector connection groove 38. As a result, the right and left retaining projections 83 engage with the right and left engagement recesses 39, so that the state of connection between the connector 80 and the connector connection projection 37 and the connector connection groove 38 is maintained unless the connector 80 is intentionally removed. When the connector 80 is connected to the connector connection projection 37 and the connector connection groove 38, the first contact segment 86 of the first contact 85 and the second contact segment 88 of the second contact 87 come into contact with the cable connecting section 20B and the cable connecting section 21 B respectively while deforming elastically.

The lighting apparatus 66 (the LED module 10) in this embodiment can be implemented in various forms. For example, the lighting apparatus 66 may be in the form illustrated in FIGS. 24 and 25.

In the LED module 10 (the LED holder 15) illustrated in FIGS. 24 and 25, the wire connecting sections 20A and 21A on the front side are connected by a wire bonding 90, and also the wire connecting sections 20A and 21A on the back side are connected by a wire bonding 90. The connector 80 of the connector-equipped cable 75 is connected to the connector connection projection 37 and the connector connection groove 38 in one part of the LED module 10, and the two cables 77 of the connector-equipped cable 75 are connected to the anode and cathode of a power source.

When a switch (not illustrated) is changed from off to on, current generated from the power source flows through the cables 77 to a parallel circuit composed of the wire connecting sections 20A, the wire connecting sections 21A, the LEDs 62, the wire bondings 64, and the wire bondings 90, as a result of which each LED 62 (in FIG. 25, all LEDs on the left side from the center of the LED module 10 are collectively indicated as “LED 62A”, and all LEDs 62 on the right side from the center of the LED module 10 are collectively indicated as “LED 62B”) emits light.

When the switch is changed from on to off, the current to the LEDs 62 is interrupted, and so each LED 62 stops emitting light.

The illumination light emitted from (the light emission surface formed on the upper surface of) each LED 62 of the lighting apparatus 66 has high (upward) straightness. Accordingly, the illumination light of each LED 62 mostly travels upward as illustrated in FIG. 21 (the arrows in FIG. 21 indicate the traveling directions of the illumination light). The remaining illumination light travels upward while (slightly) inclining with respect to the up-down direction. Thus, most of the illumination light directly travels toward the light distribution lens 70, and (part of) the remaining illumination light is reflected off the reflective film 58 and as a result travels toward the light distribution lens 70.

Part of the illumination light traveling toward the light distribution lens 70 (including the light reflected off the reflective film 58) travels to the back surface 70b. Part of the illumination light which has reached the back surface 70b passes through the inside of the light distribution lens 70 and then through the front surface 70a while avoiding the recesses 71 and 72, and travels upward from the light distribution lens 70.

Meanwhile, the illumination light which has entered any of the recesses 72 from the back surface 70b while inclining with respect to the up-down direction travels upward in the light distribution lens 70 while being reflected off the surface of the recess 72 (to change the traveling direction) and passes through the front surface 70a, and travels upward from the light distribution lens 70 while inclining.

Further, when part of the illumination light (both the light parallel to the up-down direction and the light inclining with respect to the up-down direction) which has entered the light distribution lens 70 from the back surface 70b travels to any of the recesses 71, the traveling direction of the illumination light is changed by the boundary surface between the surface of the recess 71 and the air. The illumination light then passes through the front surface 70a while inclining with respect to the up-down direction, and travels upward from the light distribution lens 70.

Thus, the light distribution lens 70 can efficiently diffuse the illumination light of each LED 62, despite being a planar lens whose front surface 70a and back surface 70b are flat surfaces parallel to each other. The illumination light emitted from the front surface 70a of the light distribution lens 70 is therefore unlikely to be uneven in luminance.

Such a lighting apparatus 66 is not only usable as a lighting device for indoor lighting and the like, but also usable in other various applications (e.g. a backlight for a liquid crystal display device).

The light distribution lens 70 is a planar lens, and so has good formability and workability. In addition, the amount of material needed to produce one light distribution lens 70 can be reduced. The light distribution lens 70 can therefore be manufactured at low cost.

Moreover, the thickness of the light distribution lens 70 is reduced, which prevents an increase in thickness of the entire lighting apparatus 66.

In the lighting apparatus 66, the reflective film 58 higher in visible light reflectivity than the primary resin molded portion 30, the LED support portion 49, and the secondary resin molded portion 54 is formed over the resin portion (the upper surfaces of the four inner projections 33, the surface of the annular wall 55, and the upper surface of the annular portion 56) and the mounting surface 49a with low visible light reflectivity in the circular pocket (the part inside the upper edges of the annular wall 55) of the upper surface of the LED module 10 (the LED holder 15) (without exposing the resin portion and the mounting surface 49a). This allows the light of the LED 62 attached to each LED fixing portion 59 (the mounting surface 49a) to be reflected with minimum loss of intensity.

The LED holder 15 is manufactured not by separately forming the components (the conductor plate 17, the primary resin molded portion 30, the heatsink 45, and the secondary resin molded portion 54) of the LED holder 15 and then assembling these components by fixing them with screws and the like, but by injection molding (insert molding) the primary resin molded portion 30 and the secondary resin molded portion 54. The LED holder 15 can thus be manufactured easily.

Since the upper surface of each inner projection 33, the mounting surface 49a of the LED support portion 49, and the upper surface of the annular portion 56 are in the same plane (continuous) and also the mounting surface 49a of the LED support portion 49 and the annular wall 55 are continuous via the upper surface of the annular portion 56 and the upper surface of each inner projection 33, the reflective film 58 can be easily and neatly formed on the upper surface of each inner projection 33, the mounting surface 49a of the LED support portion 49, the surface of the annular wall 55, and the upper surface of the annular portion 56. Such a reflective film 58 can reliably enhance the reflection efficiency of the illumination light emitted from each LED 62.

The heat generated from each LED 62 is conducted to the heatsink 45 through the reflective film 58 made up of a thin film and dissipated from the lower half (exposed part) of the heatsink 45, and also conducted to the chassis 68 from the heatsink 45 (the contact surface 48) and dissipated from the chassis 68. The heat of the LED 62 can thus be dissipated to the outside efficiently. This prevents lower light emission efficiency of the LED 62 caused by a temperature rise. Moreover, since a large LED element that generates a large amount of heat can be used as the LED 62, the light quantity can be enhanced.

The LED module 10 has the annular wall 55 (the part of the reflective film 58 formed on the annular wall 55) nearest the LEDs 62 (the light distribution lens 70), which enables the control of the directivity or emission angle of the illumination light emitted from the LEDs 62. Moreover, the reflective film 58 and the LED fixing portions 59 can be provided on the LED holder 15 in various forms (the arrangement of the LEDs 62 on the mounting surface 49a is flexible). The LED module 10 accordingly has a high degree of flexibility in optical design (easy to suppress uneven luminance of the LEDs 62, or to perform light control (brightness adjustment) and toning (adjustment of warm color, cool color, etc.)).

While the disclosed technique has been described above by way of the embodiment, the disclosure is not limited to the foregoing embodiment, and various modifications are possible.

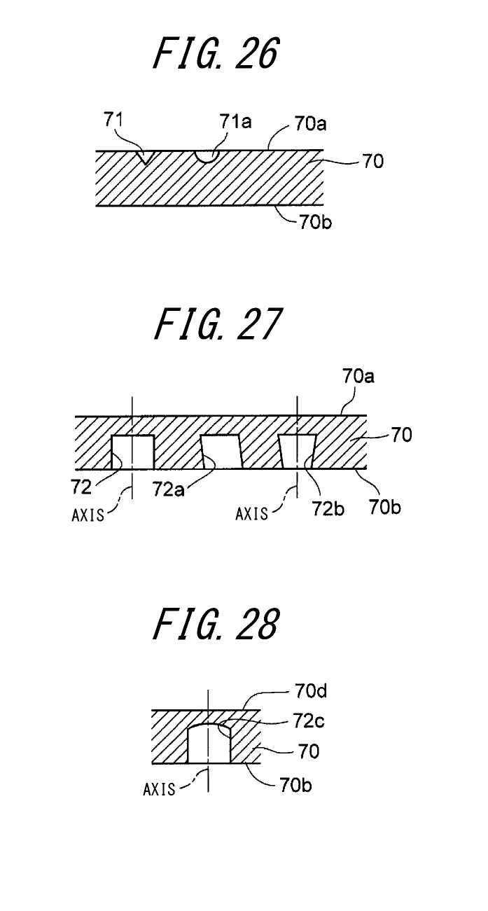

For example, modifications illustrated in FIGS. 26 to 30 may be used.

In the modification illustrated in FIG. 26, part or all of the recesses 71 formed in the front surface 70a are each changed to a hemispherical recess 71a.

In the modifications illustrated in FIGS. 27 to 29, the shape of the recesses 72 is changed.

FIG. 27 illustrates an example where part or all of the recesses 72 formed in the back surface 70b are each changed to a recess 72a or a recess 72b. The recess 72a is a recess shaped like an inclined cylinder, which is a parallelogram in a cross section (the cross section in FIG. 27) along the thickness direction of the light distribution lens 70 (a circle in a cross section along the direction orthogonal to the thickness direction). The recess 72b is a recess shaped like a truncated cone whose central axis extends in the thickness direction of the light distribution lens 70 (a trapezoid symmetric about the axis in a cross section along the thickness direction of the light distribution lens 70 as illustrated in FIG. 27).

FIG. 28 illustrates an example where part or all of the recesses 72 formed in the back surface 70b are each changed to a recess 72c. The recess 72c is a recess whose upper end part is shaped like part of a sphere (a circular arc in a cross section along the thickness direction of the light distribution lens 70 as illustrated in FIG. 28) and whose remaining part is shaped like a cylinder (whose central axis extends in the thickness direction of the light distribution lens 70).

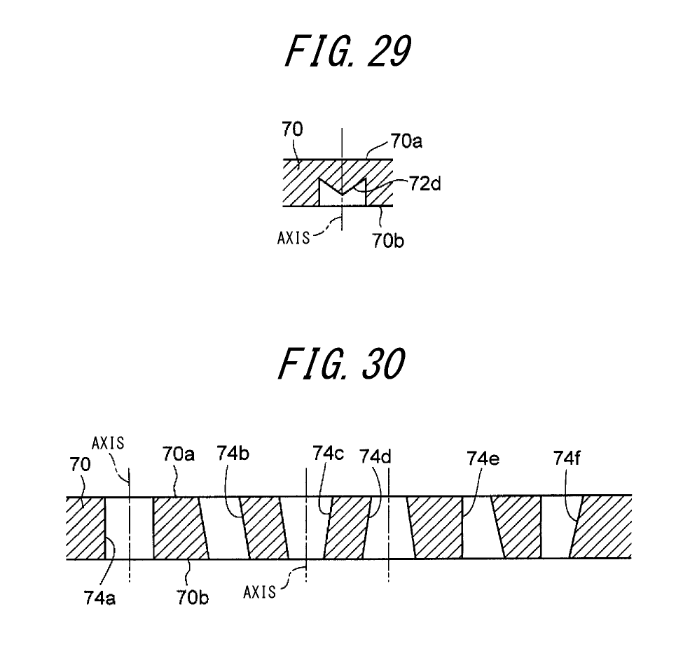

FIG. 29 illustrates an example where part or all of the recesses 72 formed in the back surface 70b are each changed to a recess 72d. The recess 72d is a recess whose upper end part is shaped like a cone projecting toward the back surface 70b and whose remaining part is shaped like a cylinder (whose central axis extends in the thickness direction of the light distribution lens 70).

In the modification illustrated in FIG. 30, instead of the recesses 71 (71a) and 72 (72a, 72b, 72c, 72d), through holes 74a, 74b, 74c, 74d, 74e, and 74f are formed in the thickness direction of the light distribution lens 70 (the positions of the through holes in the light distribution lens 70 are the same as the positions of the recesses).

The through hole 74a is a through hole shaped like a cylinder (whose central axis extends in the thickness direction of the light distribution lens 70). The through hole 74b is a through hole shaped like an inclined cylinder, which is a parallelogram in a cross section (the cross section in FIG. 30) along the thickness direction of the light distribution lens 70 (a circle in a cross section along the direction orthogonal to the thickness direction). The through hole 74c is a through hole shaped like a truncated cone whose central axis extends in the thickness direction of the light distribution lens 70 (a trapezoid symmetric about the axis in a cross section along the thickness direction of the light distribution lens 70 as illustrated in FIG. 30). The through hole 74d is a through hole having a shape vertically symmetric to the shape of the through hole 74c. The through hole 74e is a through hole shaped like a trapezoid (asymmetric about the straight line along the thickness direction of the light distribution lens 70) in a cross section (the cross section in FIG. 30) along the thickness direction of the light distribution lens 70 (a circle in a cross section along the direction orthogonal to the thickness direction). The through hole 74f is a through hole having a shape vertically symmetric to the shape of the through hole 74e.

The light distribution lens 70 may be formed by appropriately changing the positions, sizes, or numbers of the through holes 74a, 74b, 74c, 74d, 74e, and 74f or changing the combination of the types of through holes according to the distance from the LEDs 62 in the front-back direction and the right-left direction and the required light distribution property.

The modifications in FIGS. 26 to 30 can produce the same effects as the foregoing embodiment.

The through holes 74c and 74d which tend to decrease the directivity of the reflected illumination light (tend to evenly disperse the light in the direction orthogonal to the thickness direction of the light distribution lens 70) are effectively provided in a section near the LEDs 62 of the light distribution lens 70 (the area on the central side of the light distribution lens 70). On the other hand, the through holes 74b, 74e, 74f, etc. which tend to increase the directivity of the reflected illumination light (tend to reflect upward the light incident from the direction orthogonal to the thickness direction of the light distribution lens 70) are preferably provided in a section far from the LEDs 62 of the light distribution lens 70 (the area on the outer peripheral side of the light distribution lens 70) to enable the distribution of the illumination light in the specific direction.

The plurality of recesses 72 (72a, 72b, 72c, 72d) may be formed in the front surface 70a of the light distribution lens 70, and the plurality of recesses 71 (71a) in the back surface 70b of the light distribution lens 70.

Alternatively, the plurality of recesses 71 (71a) and 72 (72a, 72b, 72c, 72d) may be formed only in one of the front surface 70a and the back surface 70b.

All recesses in the front surface 70a and all recesses in the back surface 70b may be concentric (coaxial), or all recesses in the front surface 70a and all recesses in the back surface 70b may be non-concentric (non-coaxial).

The recesses in the front surface 70a and the recesses in the back surface 70b may both be arranged in a form different from the above. For example, the recesses may be arranged concentrically but not radially. Moreover, at least either the recesses in the front surface 70a or the recesses in the back surface 70b may be randomly arranged.

The through holes 74a, 74b, 74c, 74d, 74e, and 74f may be formed in the light distribution lens 70, with recesses being also formed in at least one of the front surface 70a and the back surface 70b.

The plurality of recesses 71, 71a, 72, 72a, 72b, 72c, and 72d and/or the plurality of through holes 74a, 74b, 74c, 74d, 74e, and 74f may be arranged in a grid in the light distribution lens 70.

The cross sectional shape of the recesses 71, 71a, 72, 72a, 72b, 72c, and 72d and/or the through holes 74a, 74b, 74c, 74d, 74e, and 74f in the direction orthogonal to the up-down direction (the thickness direction of the light distribution lens 70) may be a polygon instead of a circle.

The flat surface shape of the light distribution lens 70 may be a shape (e.g. a polygon) other than a circle. In this case, too, the front surface 70a and back surface 70b of the light distribution lens 70 are flat surfaces parallel to each other.

A diffusion coating higher in light diffusion function (function of diffusing upward illumination light) than the front surface 70a of the light distribution lens 70 may be applied to the front surface 70a. Instead of applying the diffusion coating to the light distribution lens 70, a rough surface (a surface rougher than the other parts of the front surface 70a) may be formed on the front surface 70a of the light distribution lens 70, to diffuse the illumination light by the rough surface.

The surfaces of the recesses 71, 71a, 72, 72a, 72b, 72c, and 72d and/or the surfaces of the through holes 74a, 74b, 74c, 74d, 74e, and 74f may be formed as glossy surfaces or rough surfaces, to change (adjust) the diffusion function of the light distribution lens 70. As an example, by forming the light distribution lens 70 having the recesses 71, 71a, 72, 72a, 72b, 72c, and 72d and/or the through holes 74a, 74b, 74c, 74d, 74e, and 74f using a molding die, the surfaces of the recesses 71, 71a, 72, 72a, 72b, 72c, and 72d and/or the surfaces of the through holes 74a, 74b, 74c, 74d, 74e, and 74f can be made glossy. As another example, by forming the light distribution lens 70 (the whole part except the recesses 71, 71a, 72, 72a, 72b, 72c, and 72d and/or the through holes 74a, 74b, 74c, 74d, 74e, and 74f) using a molding die and then forming the recesses 71, 71a, 72, 72a, 72b, 72c, and 72d and/or the through holes 74a, 74b, 74c, 74d, 74e, and 74f by cutting work, the recesses 71, 71a, 72, 72a, 72b, 72c, and 72d with rough surfaces and/or the through holes 74a, 74b, 74c, 74d, 74e, and 74f with rough surfaces can be obtained.

The light distribution lens 70 may be fixed to a member other than the LED module 10. For example, in the case where the lighting apparatus 66 is used as a backlight for a liquid crystal display device, the light distribution lens 70 may be fixed to the housing of the liquid crystal display device.

The LED holder 15 may be manufactured by, after integrally forming the part corresponding to the primary resin molded portion 30 and the secondary resin molded portion 54 with the first conductive members 20 and the second conductive members 21 beforehand, fixing the heatsink 45 to this integrated component. In this case, the part corresponding to the primary resin molded portion 30 and the secondary resin molded portion 54 may be integrally formed with the first conductive members 20 and the second conductive member 21 by injection molding (insert molding). Alternatively, after molding the part corresponding to the primary resin molded portion 30 and the secondary resin molded portion 54, the molded component may be assembled with the first conductive members 20 and the second conductive member 21.

The heatsink 45 may be made of a material other than aluminum (a material having higher thermal conductivity than the primary resin molded portion 30 and the secondary resin molded portion 54).

A heat transfer sheet or a heat transfer adhesive may be provided between the contact surface 48 of the heatsink 45 and the chassis 68.

The formation of the reflective film 58 for the inner projections 33 and/or the annular portion 56 may be omitted.

The light distribution lens 70 may be fixed to the LED holder 15 by means other than the fixing legs 73. The light distribution lens 70 may be fixed to a component (e.g. the chassis 68) other than the LED holder 15 by the fixing legs 73 or means other than the fixing legs 73 so that the LEDs 62 and the back surface 70b face each other.

The lighting apparatus according to the disclosure can efficiently diffuse illumination light of a semiconductor light-emitting element to prevent luminance unevenness and the like, despite using an optical element whose front and back surfaces are both flat.

While the present disclosure has been illustrated and described with respect to a particular embodiment thereof, it should be appreciated by those of ordinary skill in the art that various modifications to this disclosure may be made without departing from the spirit and scope of the present disclosure.

What is claimed is:

1. A lighting apparatus comprising:
a base member;
a semiconductor light-emitting element fixed to the base member; and
an optical element whose surface facing the semiconductor light-emitting element and surface on an opposite side to the semiconductor light-emitting element are flat surfaces parallel to each other,
wherein the optical element has a plurality of at least either recesses or through holes, in at least one of the facing surface and the opposite surface.

2. The lighting apparatus according to claim 1,
wherein at least either the recesses or the through holes are formed in the facing surface and the opposite surface.

3. The lighting apparatus according to claim 2,
wherein the recesses formed in the facing surface and the recesses formed in the opposite surface are concentric with each other.

4. The lighting apparatus according to claim 1,
wherein at least either the recesses or the through holes are arranged concentrically.

5. The lighting apparatus according to claim 1,
wherein at least either the recesses or the through holes are arranged radially.

6. The lighting apparatus according to claim 1,
wherein at least either the recesses or the through holes are arranged in a grid.

7. The lighting apparatus according to claim 1,
wherein at least one of the recesses is shaped like a cone.

8. The lighting apparatus according to claim 1,
wherein at least one of the recesses is shaped like a hemisphere.

9. The lighting apparatus according to claim 1,
wherein at least one of the recesses has a bottom surface shaped like a part of a spherical surface, and a part except the bottom surface shaped like a cylinder.

10. The lighting apparatus according to claim 1,
wherein at least one of the recesses has a bottom surface shaped like a cone projecting toward an open end of the recess, and a part except the bottom surface shaped like a cylinder.

11. The lighting apparatus according to claim 1,
wherein at least one of the recesses and/or at least one of the through holes is shaped like a cylinder.

12. The lighting apparatus according to claim 1,
wherein at least one of the recesses and/or at least one of the through holes is shaped like a truncated cone.
